(19) United States
(12) Patent Application Publication
(10) Pub. No.: US 2017/0012377 A1
(43) Pub. Date: Jan. 12, 2017

(54) ELECTRICAL COMPONENT AND ELECTRONIC DEVICE

(71) Applicant: DENSO CORPORATION, Kariya-city (JP)

(72) Inventor: Kenji OCHI, Kariya-city (JP)

(21) Appl. No.: 15/200,350

(22) Filed: Jul. 1, 2016

(30) Foreign Application Priority Data
Jul. 9, 2015 (JP) 2015-138057
Feb. 15, 2016 (JP) 2016-26076

(51) Int. Cl. H01R 12/72; H05K 1/11; H01R 13/03

(52) U.S. Cl. CPC H01R 12/721; H01R 13/03; H05K 1/117; H05K 2201/0338

(57) ABSTRACT

An electrical component includes a contact point part that establishes an electrical connection by contact. In addition, the contact point part includes: a substrate having a metal as a constituent material; and a thin film arranged at a surface of the substrate. Moreover, the thin film includes a π-accepting molecule having a π-acceptability, in which the π-accepting molecule has a size of ligand field splitting in a spectrochemical series larger than or equal to a size of ligand field splitting of 2,2′-bipyridyl.

### CROSS REFERENCE TO RELATED APPLICATIONS

This application is based on Japanese Patent Applications No. 2015-138057 filed on Jul. 9, 2015, and No. 2016-26076 filed on Feb. 15, 2016, the disclosures of which are incorporated herein by reference.

### TECHNICAL FIELD

The present disclosure relates to: an electrical component having a contact point part that establishes electrical connection by contact; and an electronic device provided with the electrical component.

### BACKGROUND

Conventionally, an electrical component has been known which is provided with a contact point part that establishes electrical connection by contact, such as a terminal having a spring property, or a board having a connector or a land provided with the terminal. With regard to this electrical component, there is a difficulty of increase in contact resistance caused by oxidation of a metal surface at the contact point part. On the metal surface, electrons are localized such as in a dangling bond (unbonded hand) on a semiconductor surface. On the other hand, an oxygen molecule has two unpaired electrons. For this reason, it seems that the oxygen molecules and the metal share electrons with each other, and the oxygen molecules are adsorbed onto the metal surface to cause the oxidation. In other words, it seems that, because a surface level is formed on the metal surface by localization of electrons, the oxygen molecules having unpaired electrons are trapped at the surface level to cause the oxidation.

In order to solve the aforementioned difficulty, a configuration is known in which the uppermost surface of the contact point part is plated with gold. However, when gold is abraded by relative displacement of the contact point parts with each other, that is, by sliding, the metal in the underlayer is exposed, and the underlayer metal is oxidized. For this reason, the gold plating must be provided in a large thickness, leading to increase in the cost.

Patent Literature 1 discloses a configuration for solving the aforementioned difficulty without using gold. The disclosed electrical contact element (electrical component) has a covering layer which serves as a contact point part and which is formed on a surface of a core body (substrate). The covering layer contains a chemical reducing agent (hereafter referred to as “reducing agent”). As the sliding proceeds, the reducing agent is released from the covering layer to reduce the metal oxide on the surface of the covering layer.

The configuration disclosed in Patent Literature 1 raises a difficulty in that, when a reducing capability of the reducing agent existing on the surface of the covering layer is lost, the metal on the surface of the covering layer is oxidized. For this reason, it is difficult to suppress the increase in the contact resistance caused by oxidation for a long period of time.
[Patent Literature 1] JP2014-519157A (Corresponding to US2014/0102759)

### SUMMARY

It is an object of the present disclosure to provide an electrical component and an electronic device which are inexpensive and can suppress the increase in the contact resistance caused by oxidation for a long period of time.

An electrical component according to a first aspect of the present disclosure includes a contact point part that establishes an electrical connection by contact. In addition, the contact point part includes: a substrate having a metal as a constituent material; and a thin film arranged at a surface of the substrate. Moreover, the thin film includes a π-accepting molecule having a π-acceptability, in which the π-accepting molecule has a size of ligand field splitting in a spectrochemical series larger than or equal to a size of ligand field splitting of 2,2″-bipyridyl.

An electronic device according to a second aspect of the present disclosure includes: a first component that has a first contact point part; and a second component that has a second contact point part electrically connected to the first contact point part by being in contact with the first contact point part. At least one of the first component and the second component includes the electric component according to the first aspect of the present disclosure.

In the following, the localization of electrons on the metal surface is expressed as a dangling bond on the metal surface. According to the both first and second aspects of present disclosure, the π-accepting molecule forms a back-donation π-bond to the metal having a dangling bond. This can reduce or eliminate the number of dangling bonds on the metal surface at the contact point parts as compared with conventional cases. Therefore, oxidation of the metal surface can be suppressed at the contact point parts.

Also, the back-donation π-bond suppresses oxidation of the metal surface. Therefore, increase in the contact resistance can be suppressed for a longer period of time than in the conventional cases.

Also, because gold is not used, oxidation of the metal surface can be suppressed at a low cost.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a sectional view illustrating a schematic configuration of an electronic device according to the first embodiment;

FIG. 2 is an enlarged sectional view illustrating peripheries of an electrical contact point between a land and a contact point part of a terminal;

FIG. 3 is a view illustrating a molecular structure of a π-accepting molecule;

FIG. 4 is a view illustrating a molecular structure of a π-accepting molecule;

FIG. 5 is a view showing a first reference example;

FIG. 6 is a view showing a second reference example;

FIG. 7 is a view illustrating an effect of the first embodiment;

FIG. 8 is a view showing results of XPS measurement in Example 1;

FIG. 9 is a view showing results of XPS measurement in Comparative Example 1;

FIG. 10 is a view describing a testing method in Example 2;

FIG. 11 is a view illustrating a relationship between the number of sliding operations at room temperature and a contact resistance in Example 2;

FIG. 12 is a view illustrating a relationship between the number of sliding operations at a high temperature and a contact resistance in Example 2;

FIG. 13 is a view illustrating a result of comparison between Example 2 and Comparative Example 2;

FIG. 14 is an enlarged sectional view illustrating peripheries of an electrical contact point between a land and a contact point part of a terminal in an electronic device according to a second embodiment;

FIG. 15 is a view illustrating an effect of the second embodiment; and

FIG. 16 is an enlarged sectional view illustrating peripheries of an electrical contact point between a land and a contact point part of a terminal in an electronic device according to a third embodiment.

### DETAILED DESCRIPTION

Hereafter, embodiments of the present disclosure will be described with reference to the attached drawings. Here, in each of the embodiments, common or related elements will be denoted with the same reference signs. In the following, a thickness direction of a board is set as a Z-direction, and a direction which is perpendicular to the Z-direction and is a depth direction of an insertion space of a card edge connector into which a circuit board is inserted is set as a Y-direction. Also, a direction which is perpendicular to both of the Z-direction and the Y-direction and is a width direction of the insertion space is set as an X-direction.

### First Embodiment

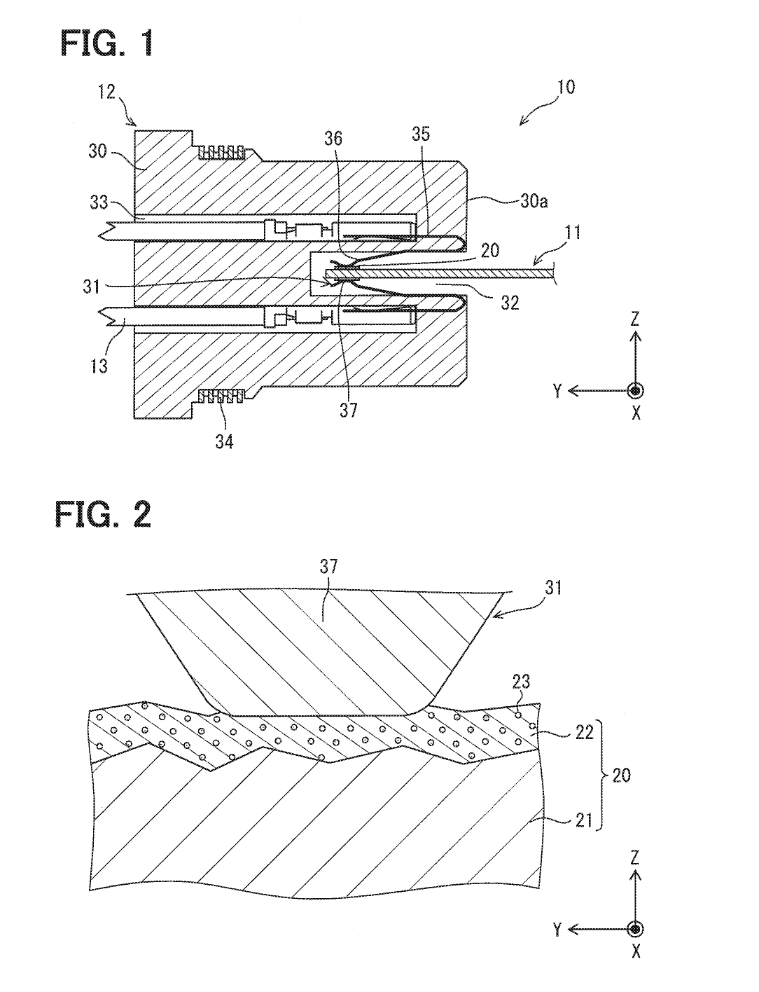

First, a schematic configuration of an electronic device 10 will be described with reference to FIG. 1.

The electronic device 10 shown in FIG. 1 is mounted, for example, on a vehicle. The electronic device 10 is configured as an electronic controlling device that controls the vehicle. The electronic device 10 is configured, for example, as an engine ECU (Electronic Control Unit) that controls an engine mounted on the vehicle.

The electronic device 10 includes a board 11 and a card edge connector 12. The board 11 corresponds to the first component described, and the card edge connector 12 corresponds to the second component. Also, the board 11 corresponds to the electrical component.

The board 11 is what is known as a printed circuit board. Electronic components not illustrated in the drawings are mounted on the board 11. The board 11 has a plurality of lands 20 as electrodes for establishing electrical connection to the card edge connector 12. These lands 20 correspond to the first contact point part and the contact point part. The lands 20 are formed at one end in the Y-direction on the board 11. The lands 20 are formed at a tip end of insertion into the card edge connector 12 on the board 11. The plurality of lands 20 are arranged in the X-direction on a surface of the board 11 in the Z-direction. In the present embodiment, the lands 20 are arranged on both surfaces of the board 11.

The card edge connector 12 is a relay member that establishes electrical connection between the board 11 and an external apparatus. The card edge connector 12 has a housing 30 made of an electrically insulating material, and a terminal 31 held by the housing 30.

The housing 30 is formed, for example, by injection molding of a resin. The housing 30 has an insertion space 32 into which the board 11 is inserted and arranged. The insertion space 32 opens to a tip end surface 30a of the housing 30. The housing 30 has a storage space 33 that stores a harness 13 for connection to the external apparatus. When the harness 13 is inserted into the storage space 33, electrical connection is established between the terminal 31 and the harness 13.

Here, a sealing member 34 made, for example, of a silicone rubber is disposed in a ring configuration along an outer circumferential surface of the housing 30. For this reason, when the housing 30 is fitted into a box not illustrated in the drawings, the sealing member 34 can prevent penetration of moisture and the like into an internal space of the box through a gap between the inner surface of the box and an outer surface of the housing 30. In this case, the board 11 is housed in the box. The box also is a constituent element of the electronic device 10.

The terminal 31 is formed by using a metal material having a good electrical conductivity. A holding part 35, which is one part of the terminal 31, is held by the housing 30. The terminal 31 has a protrusion 36 that extends from the holding part 35 to protrude into the insertion space 32. The protrusion 36 has a contact point part 37 which is a part that is brought into contact with the land 20. This contact point part 37 corresponds to the second contact point part. The contact point part 37 is a part that is the closest to the board 11 in the Z-direction among the parts of the protrusion 36.

The contact point part 37 is brought into contact with the land 20 in a state where at least the protrusion 36 of the terminal 31 is elastically deformed. Therefore, a stable contact pressure can be ensured between the contact point part 37 and the land 20 of the board 11. In the present embodiment, the protrusion 36 protrudes into the insertion space 32 from side walls that oppose each other in the Z-direction of the insertion space 32. The board 11 is fixed by a reactive force (urging force) generated by elastic deformation of the protrusion 36 located on both surfaces of the board 11.

Next, with reference to FIG. 2, a configuration of peripheries of an electrical contact point between the land 20 of the board 11 and the contact point part 37 of the terminal 31 will be described. FIG. 2 shows a model view of a dispersion state of a π-accepting molecule 23 described later.

The land 20 is formed on a surface of an electrically insulating substrate (not illustrated in the drawings), such as a glass epoxy resin, constituting the board 11. The land 20 has an underlayer metal part 21 and a plated film 22 formed on the surface of the electrically insulating substrate. This underlayer metal part 21 corresponds to the substrate, and the plated film 22 corresponds to the thin film. The land 20 is an electrode, so that the underlayer metal part 21 is also referred to as an electrode substrate. Also, the land 20 constitutes a contact point part of the board 11 and forms an electrical contact point with the contact point part 37, so that the underlayer metal part 21 is also referred to as an electrical contact point substrate.

The underlayer metal part 21 is formed by using a metal material having a good electrical conductivity. In the present embodiment, the underlayer metal part 21 is formed by using copper. The underlayer metal part 21 is formed by patterning a copper foil bonded to the surface of the electrically insulating substrate.

The plated film 22 is formed on a surface of the underlayer metal part 21. The plated film 22 is formed to contain, as a major component, a metal material that can form a back-donation π-bond with π-accepting molecules 23 described later and can be formed on the underlayer metal part 21. The plated film 22 contains, for example, one of Ni, Cu, Ag, and Co as a major component. Among the aforementioned metals, Ni, Cu, Ag, and Co are transition metals. In the present embodiment, the plated film 22 is formed by using copper as a constituent material. The plated film 22 is formed, for example, by performing electrolytic copper plating after nonelectrolytic copper plating is carried out. A thickness of the plated film 22 is within a range of 0.1 μm to 100 μm.

In this plated film 22, the π-accepting molecules 23 are dispersed. The plated film 22 in which the π-accepting molecules 23 are dispersed can be formed by putting the π-accepting molecules into a plating bath and performing plating on the underlayer metal part 21 in a mixed and stirred state.

The π-accepting molecule 23 is a molecule having a π-acceptability in which a size of ligand field splitting thereof in a spectrochemical series is larger than or equal to that of 2,2′-bipyridyl. The π-accepting molecule 23 is a molecule having a high π-acceptability. The π-acceptability is also referred to as π-acidity. The size of ligand field splitting is an energy difference of d-orbit splitting. The π-accepting molecule 23 is a molecule that can accept electron density in a vacant π-orbit to form a back-donation π-bond between the metal and the π-accepting molecule 23. For this reason, the π-accepting molecule 23 is also referred to as a π-accepting ligand, and forms a complex by being coordinated to the metal. The π-acceptability is proportional to the size of ligand field splitting. In the following, the known spectrochemical series is shown. In the exemplification, the molecule providing the largest ligand field splitting is CO.

I⁻<Br⁻<Cl⁻<OH⁻<H₂O<py<NH₃<en<bpy<phen<NO₂⁻<PPh₃<CN⁻<CO

Herein, py denotes pyridine; en denotes ethylenediamine; bpy denotes 2,2′-bipyridyl; phen denotes 1,10-phenanthroline; and PPh₃ denotes triphenylphosphine. In the following, 2,2′-bipyridyl is referred to as bpy, and 1,10-phenanthroline is referred to as phen.

The π-accepting molecule 23 to be used may be, for example, bpy, a bpy analog, phen, or a phen analog. It is possible to adopt a configuration which contains at least one of bpy and a bpy analog as the π-accepting molecule 23. For example, the plated film 22 may contain two kinds of bpy analogs, or may contain both of bpy and a bpy analog. Also, it is possible to adopt a configuration in which the plated film 22 contains bpy alone as the π-accepting molecule 23. Also, it is possible to adopt a configuration which contains at least one of phen and a phen analog as the π-accepting molecule 23. For example, the plated film 22 may contain two kinds of phen analogs, or may contain both of phen and a phen analog. Also, it is possible to adopt a configuration in which the plated film 22 contains phen alone as the π-accepting molecule 23.

Each of bpy, a bpy analog, phen, and a phen analog has a nitrogen atom having a lone electron pair. Each of bpy, a bpy analog, phen, and a phen analog is a multidentate ligand that has two nitrogen atoms having a lone electron pair. Each of bpy, a bpy analog, phen, and a phen analog is a π-conjugated molecule. As shown in the later-described Examples, it has been confirmed by the present inventors that these exemplified π-accepting molecules 23 suppress oxidation of a metal surface.

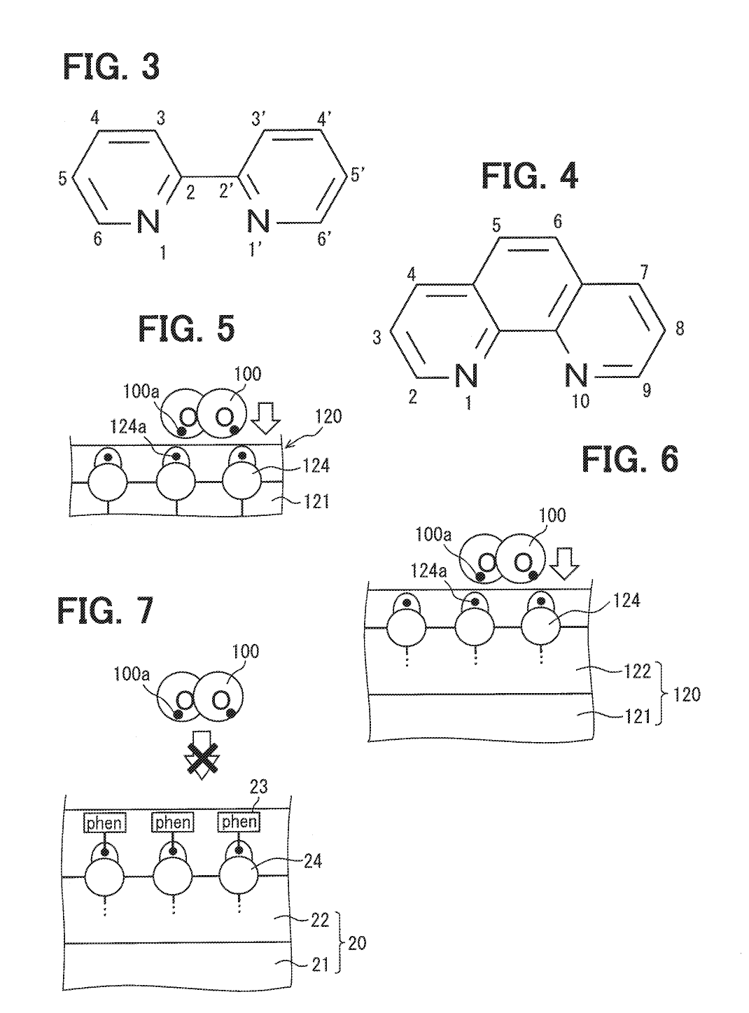

Here, FIG. 3 shows a molecular structure of bpy, and FIG. 4 shows a molecular structure of phen. In FIGS. 3 and 4, position numbers are shown. In bpy, hydrogen is bonded to carbon at 3-, 4-, 4′-, 5-, 5′-, 6-, and 6′-positions. The bpy analogs include those having a structure similar to that of bpy, for example, those in which an alkyl group is bonded in place of hydrogen to carbon at 4-, 4′-, 5-, 5′-, 6-, or 6′-position of bpy. In other words, the bpy analogs are obtained by substituting hydrogen of bpy with another functional group. In the case of phen, hydrogen is bonded to carbon at 2- to 9-positions. The same applies to the phen analogs as well.

Next, with reference to FIGS. 5 to 7, an effect of the board 11 (electrical component) and the electronic device 10 mentioned above will be described. FIG. 5 shows a first Reference Example, and FIG. 6 shows a second Reference Example. In FIGS. 5 and 6, elements common to or related to the elements of the present embodiment are denoted with reference signs obtained by each adding 100 to the reference signs of the respective elements of the present embodiment. FIGS. 5 to 7 show model views of metal atoms, dangling bonds, oxygen molecules, and unpaired electrons. A crystal structure of the metal is not particularly limited.

In the first Reference Example shown in FIG. 5, a land 120 which is a contact point part has only an underlayer metal part 121, and does not have a plated film 122. For this reason, electrons are localized on a surface of the underlayer metal part 121 which is a metal surface in the land 120, as in dangling bonds (unbonded hands) on a semiconductor surface. In the following, the localization of electrons on the metal surface is denoted as dangling bonds on the metal surface. Referring to FIG. 5, metal atoms 124 located on the surface of the underlayer metal part 121 have dangling bonds 124a,

Meanwhile, an oxygen molecule 100 has two unpaired electrons 100a, as shown in FIG. 5. For this reason, it seems that the oxygen molecules 100 and the metal having dangling bonds 124a share electrons with each other, so that the oxygen molecules 100 are adsorbed onto the metal surface, thereby leading to oxidation. In other words, it seems that a surface level is formed on the metal surface by the localization of electrons, so that the oxygen molecules 100 having unpaired electrons 100a are trapped by the surface level, thereby leading to oxidation.

In the second Reference Example shown in FIG. 6, a land 120 which is a contact point part has a plated film 122 together with an underlayer metal part 121. In this configuration, a surface of the plated film 122 is a metal surface in the land 120. Further, metal atoms 124 located on the surface of the plated film 122 have dangling bonds 124a. For this reason, it seems that the oxygen molecules 100 and the metal having dangling bonds 124a share electrons with each other, so that the oxygen molecules 100 are adsorbed onto the metal surface, thereby leading to oxidation.

In this manner, in each of the cases of the first Reference Example and the second Reference Example that show conventional configurations, oxidation proceeds on the metal surface of the land 120.

In the present embodiment, a land 20 which is a contact point part has a plated film 22 together with an underlayer metal part 21, as shown in FIG. 7. For this reason, a surface of the plated film 22 is a metal surface in the land 20, as shown in the second Reference Example. Further, π-accepting molecules 23 are dispersed in the plated film 22, as described above. In FIG. 7, phen is dispersed as the π-accepting molecules 23.

As described above, the π-accepting molecule 23 can accept electron density in a vacant π-orbit to form a back-donation π-bond between the metal and the π-accepting molecule 23. The π-accepting molecule 23 is a molecule in which a size of ligand field splitting thereof in a spectrochemical series is larger than or equal to that of bpy, and has a high π-acceptability. For this reason, the energy of the vacant π-orbit of the π-accepting molecule 23 is close to the energy of the occupied d-orbit of the metal, whereby the π-orbit interacts with the d-orbit to generate delocalization of electrons from the metal towards the π-accepting molecule 23. In other words, the π-accepting molecules 23 form a back-donation π-bond between the metal atoms 24 constituting the plated film 22 and the π-accepting molecules 23. Here, the coordinated atom of the π-accepting molecule 23 has a lone electron pair, and the σ-orbit of the coordinated atom interacts with a vacant orbit (for example, d-orbit) of the metal to form a σ-bond.

In this manner, in the present embodiment, the π-accepting molecules 23 form a back-donation π-bond to the metal atoms 24 having a dangling bond. This can reduce or eliminate the number of dangling bonds on the metal surface at the land 20, which is the contact point part, as compared with conventional cases. Therefore, oxidation of the metal surface can be suppressed at the land 20.

Meanwhile, in the case of a reducing agent, the oxidation proceeds when the reducing capability is lost. In contrast, the π-accepting molecules 23 suppress oxidation of the metal surface by being bonded to the metal atoms 24 having a dangling bond. As long as the bonded state is maintained, the oxidation can be suppressed. As described above, the π-accepting molecules 23 are coordinated to the metal atoms 24 by the back-donation π-bond in addition to the σ-bond. Therefore, increase in the contact resistance can be suppressed for a longer period of time than in the conventional cases.

Also, because gold is not used, oxidation of the metal surface can be suppressed at a low cost.

Also, it is good to use a phen analog in which an electron-attracting group is bonded to at least one position among the 2- to 9-positions of phen as the π-accepting molecule 23. When an electron-attracting group is introduced in place of hydrogen, the π-acceptability increases by the electron-attracting property. In other words, the dangling bonds of the metal can be more easily drawn to the phen-side. This improves the bonding strength. Therefore, increase in the contact resistance can be suppressed for a long period of time even at a high temperature. In other words, the heat resistance is improved, enabling use in a wider temperature range. Here, a nitro group, an aldehyde group, a carboxy group, a cyano group, and the like can be used as the electron-attracting group.

Regarding the improvement in heat resistance, the same applies to bpy as well. Specifically, it is good to use a bpy analog in which an electron-attracting group is introduced to at least one position among the 3- to 6- and 3′- to 6′-positions of bpy as the π-accepting molecule 23. This increases the π-acceptability to a greater extent, and the heat resistance is improved.

Next, specific Examples confirmed by the present inventors will be described.

### Example 1

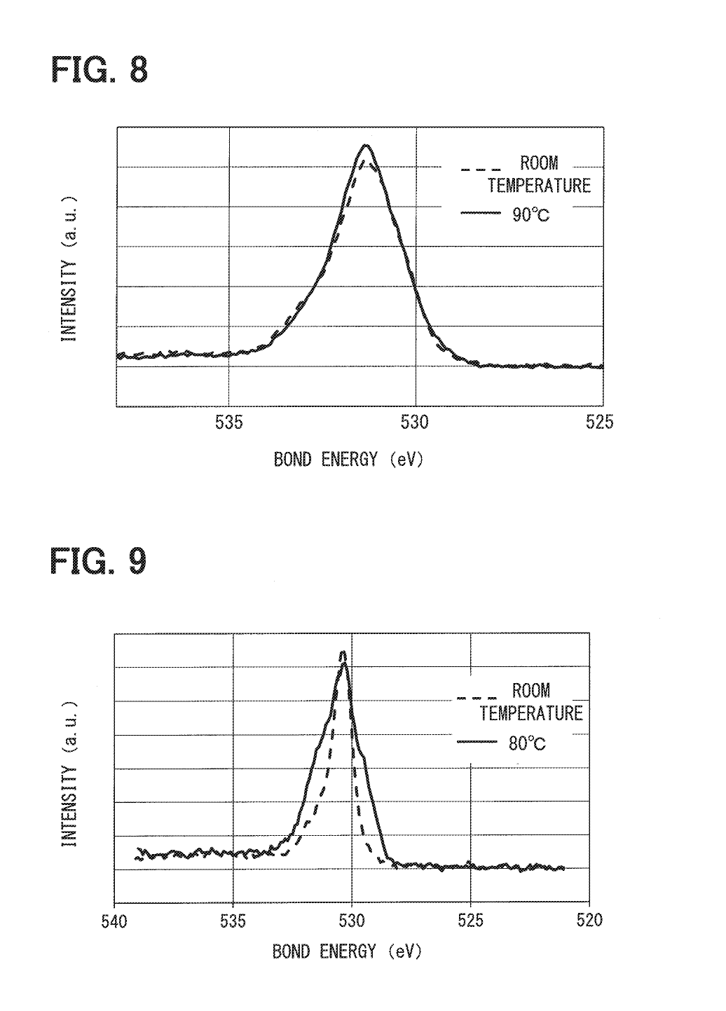

The present inventors have confirmed a relationship between the presence or absence of the π-accepting molecules 23 and the oxidation of the metal surface. Specifically, a substrate having a flat plate shape and containing phosphor bronze as a constituent material was prepared. The dimension of the substrate was set to be 20 mm×20 mm. Further, phen constituting the π-accepting molecules 23 and an additive were added into a plating bath containing copper as a major component, followed by stirring. Thereafter, a test piece was prepared by forming a plated film on a surface of the substrate. This test piece was analyzed by XPS (X-ray Photoelectron Spectroscopy) at room temperature (25° C.). Also, the test piece was heated by a hot plate, and the temperature of the test piece was maintained at 90° C. for 3 hours. The test piece after heating for 3 hours was analyzed by XPS. The results of analysis are shown in FIG. 8. In FIG. 8, the broken line represents room temperature, and the solid line represents 90° C.

Also, as Comparative Example 1, a test piece that did not contain the π-accepting molecules 23 (phen) in the plated film was prepared. This test piece also was analyzed by XPS at room temperature and at 80° C. The results of analysis are shown in FIG. 9. In FIG. 9, the broken line represents room temperature, and the solid line represents 80° C.

Here, the peak of cupric oxide (CuO) appears at 529.5 eV, and the peak of cuprous oxide (Cu₂O) appears at 530.5 eV, In the case of Example 1, little change was seen in the intensity at 529.5 eV between room temperature and 90° C., as shown in FIG. 8. Also, little change was seen in the intensity at 530.5 eV as well. From this, it is understood that the oxidation of the metal surface was suppressed in Example 1.

In contrast, in the case of Comparative Example 1, increase in the area of a band having a peak at 529.5 eV was confirmed at room temperature, as shown in FIG. 9, even though the heating temperature had been set to be 80° C. which was lower than that of the Example. Also, a shoulder was confirmed at 530.5 eV at 80° C. From this, it is understood that the oxidation of the metal surface proceeded in Comparative Example 1 that did not contain the it-accepting molecules 23 in the plated film. Here, similar results were obtained with respect to bpy as well.

### Example 2

The present inventors have confirmed the effects of substituents and heat resistance.

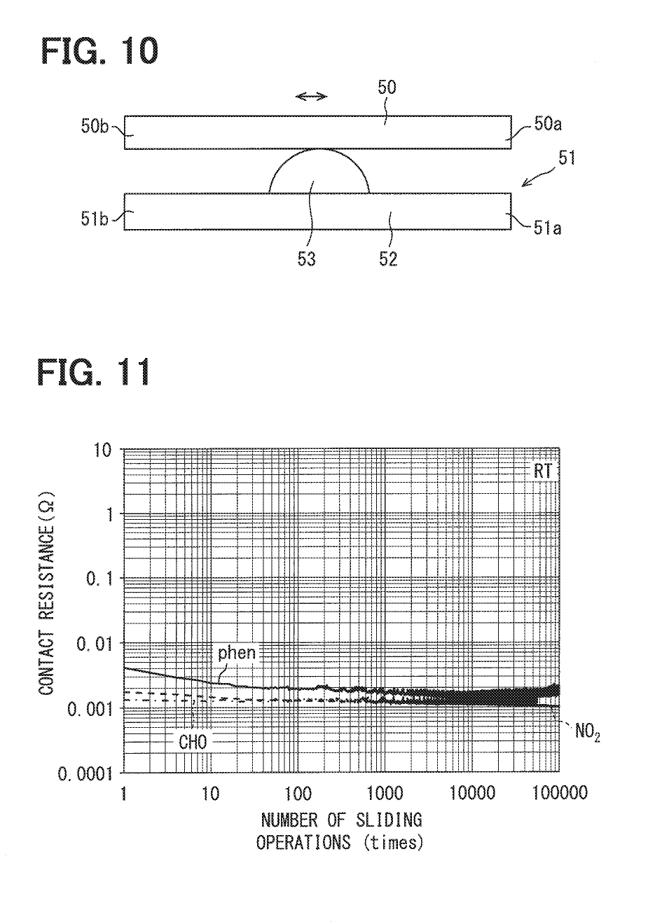

First, referring to FIG. 10, a first member 50 and a second member 51 were prepared. Specifically, a flat plate of 20 mm×20 mm containing phosphor bronze as a constituent material was put into a plating bath containing copper as a major component. Into the plating bath, π-accepting molecules 23 and an additive were added and stirred, so as to form a plated film on a surface of the flat plate, thereby to form the first member 50. Also, a metal member was prepared which had a flat plate part 52 of 20 mm×20 mm containing phosphor bronze as a constituent material and a convex part 53 having a hemispherical shape formed near a center of a surface of the flat plate part 52 that faces the first member 50. Here, the convex part 53 was set to have R1 (radius of 1 mm). Further, a plated film was formed on a surface of the metal member in the same manner as in the first member 50, so as to form the second member 51.

Referring to FIG. 10, the first member 50 was stacked on a surface where the convex part 53 had been formed in the flat plate part 52 so that the first member 50 and the flat plate part 52 would overlap with each other in a projection view from a plate thickness direction. Further, in a state where a predetermined load (for example, 3N) is applied in a stacking direction from the first member 50 side, the first member 50 and the second member 51 were mutually slid finely and minutely with each other in a direction perpendicular to the stacking direction (direction indicated by an arrow in FIG. 10). The reciprocal distance of sliding, that is, a distance per one sliding operation, was set in a plurality of levels. FIGS. 11 to 13 described later show results when the distance per one sliding operation was set to be 50 μm. Here, the same tendency was seen even when the distance was changed.

Also, a contact resistance was measured for each sliding operation. At that time, a terminal for measurement was attached to each of a terminal end 50a and a terminal end 50b, which respectively constituted one side and the other side of the first member 50 that opposed each other. Further, a terminal for measurement was attached to each of a terminal end 51a and a terminal end 51b, which respectively constituted one side and the other side of the flat plate part 52 of the second member 51 that opposed each other. Here, assuming that the opposing direction of the two sides where the terminal ends 50a and 50b were provided is the first direction, the opposing direction of the two sides where the terminal ends 51a and 51b in the second member 51 were provided was set to be the same first direction. Also, in the first direction, the terminal ends 50a, 51a were placed to be on the same side as each other, and the terminal ends 50b, 51b were placed to be on the same side as each other. Further, in a manner in which the convex part 53 was interposed in-between, a contact resistance in an energization path between the terminal end 50a of the first member 50 and the terminal end 51b of the second member 51 or a contact resistance in an energization path between the terminal end 50b of the first member 50 and the terminal end 51a of the second member 51 was measured.

As the π-accepting molecule 23, phen, a phen analog in which a nitro group (NO₂) had been introduced to the 5-position thereof, and a phen analog in which an aldehyde group (CHO) had been introduced to the 2-position thereof were respectively used. Further, the contact resistance was measured both at room temperature (25° C.) and at 125° C. for each of the respective cases.

Also, as Comparative Example 2, a first member and a second member were prepared which had been subjected to gold plating instead of forming a plated film containing the π-accepting molecules 23. Thereafter, a similar sliding test was carried out.

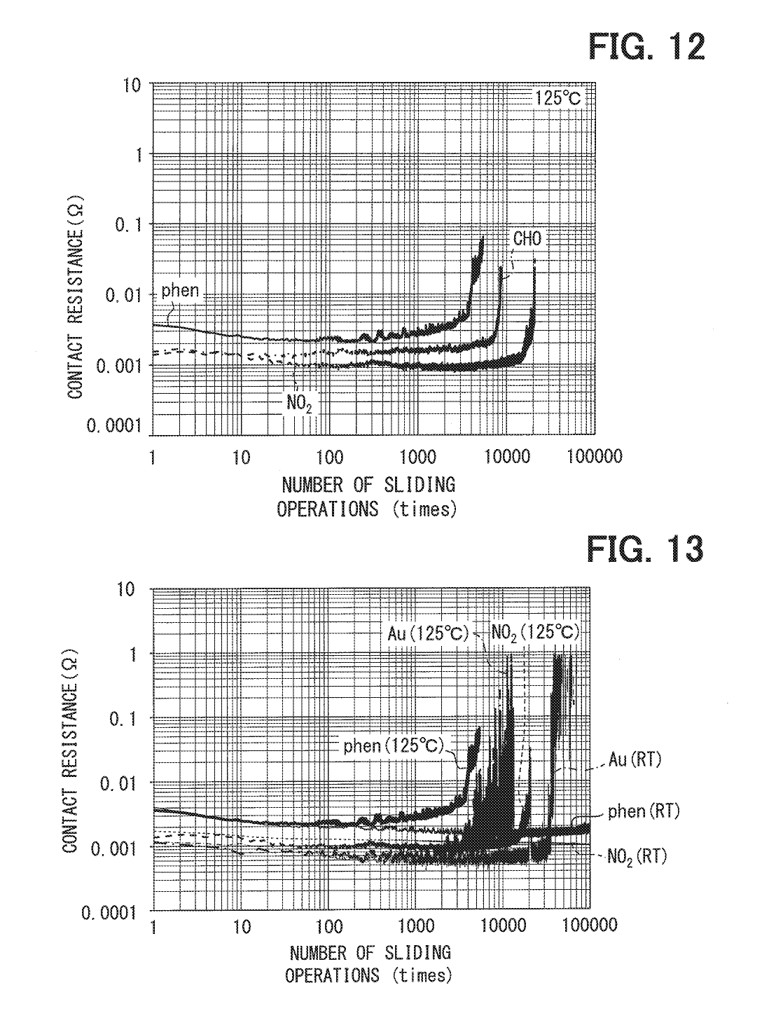

FIG. 11 shows a result of the sliding test at room temperature. FIG. 12 shows a result of the sliding test at 125° C. FIG. 13 shows results of the cases of phen and the phen analog in which a nitro group (NO₂) had been introduced to the 5-position thereof in Example 2 and the case of Comparative Example 2 together. In FIG. 11, phen is shown by a solid line; the phen analog in which a nitro group had been introduced is shown by a broken line; and the phen analog in which an aldehyde group had been introduced is shown by a one-dot chain line. In FIG. 12, phen is shown by a solid line; the phen analog in which a nitro group had been introduced is shown by a broken line; and the phen analog in which an aldehyde group had been introduced is shown by a one-dot chain line. In FIG. 13, phen is shown by a solid line; the phen analog in which a nitro group had been introduced is shown by a broken line; and gold (Au) in the case of Comparative Example 2 is shown by a one-dot chain line. Here, in FIG. 13, the case of room temperature is shown by a thin line, and the case of 125° C. is shown by a thick line which is thicker than that of the case of room temperature.

Referring to FIG. 11, a stable contact resistance was exhibited even after 50,000 sliding operations at room temperature in each of the cases of the phen, the phen analog in which an electron-attracting nitro group had been introduced to the 5-position thereof, and the phen analog in which an electron-attracting aldehyde group had been introduced to the 2-position thereof.

Referring to FIG. 12, a stable contact resistance was exhibited even after 2,000 sliding operations at 125° C. in each of the cases of the phen, the phen analog in which an electron-attracting nitro group had been introduced to the 5-position thereof, and the phen analog in which an electron-attracting aldehyde group had been introduced to the 2-position thereof. Specifically, in the case of phen, a stable contact resistance was exhibited up to about 2,000 sliding operations. In the case of the phen analog in which a nitro group had been introduced, a stable contact resistance was exhibited up to about 10,000 sliding operations. In the case of the phen analog in which an aldehyde group had been introduced, a stable contact resistance was exhibited up to about 7,000 sliding operations. In other words, the phen analogs in which an electron-attracting group had been introduced suppressed increase in the contact resistance for a longer period of time than the phen. Also, though the kind of the substituent is different, the phen analog in which an electron-attracting group had been introduced to the 5-position thereof suppressed increase in the contact resistance for a longer period of time than the phen analog in which an electron-attracting group had been introduced to the 2-position thereof.

Referring to FIG. 13, at room temperature, the phen suppressed increase in the contact resistance for a longer period of time than the gold of Comparative Example 2. Meanwhile, at 125° C., the phen invited increase in the contact resistance a little earlier than the gold. On the other hand, the phen analog in which an electron-attracting nitro group had been introduced to the 5-position thereof suppressed increase in the contact resistance for a longer period of time than the gold both at room temperature and at 125° C.

From the above, it has been made clear that, when the thin film contains the π-accepting molecules 23, increase in the contact resistance can be suppressed for a long period of time. In particular, it has been made clear that it is good to contain at least one of phen and a phen analog as the π-accepting molecule 23. Further, it has been made clear that, by using a phen analog in which an electron-attracting group has been introduced, the heat resistance is improved, and increase in the contact resistance can be suppressed for a long period of time in a wider temperature range.

Here, in Example 2, phen and a phen analog in which an electron-attracting group had been introduced were used as the π-accepting molecule 23; however, it seems that similar results can be obtained even when bpy and a bpy analog in which an electron-attracting group has been introduced are used. In other words, it is good to contain at least one of bpy and a bpy analog as the π-accepting molecule 23. Further, it is good to use a bpy analog in which an electron-attracting group has been introduced to at least one of the 2- to 9-positions.

### Second Embodiment

For the present embodiment, reference can be made to the embodiment described before. For this reason, description of the parts common to those of the electronic device 10 shown in the embodiment described before will be omitted.

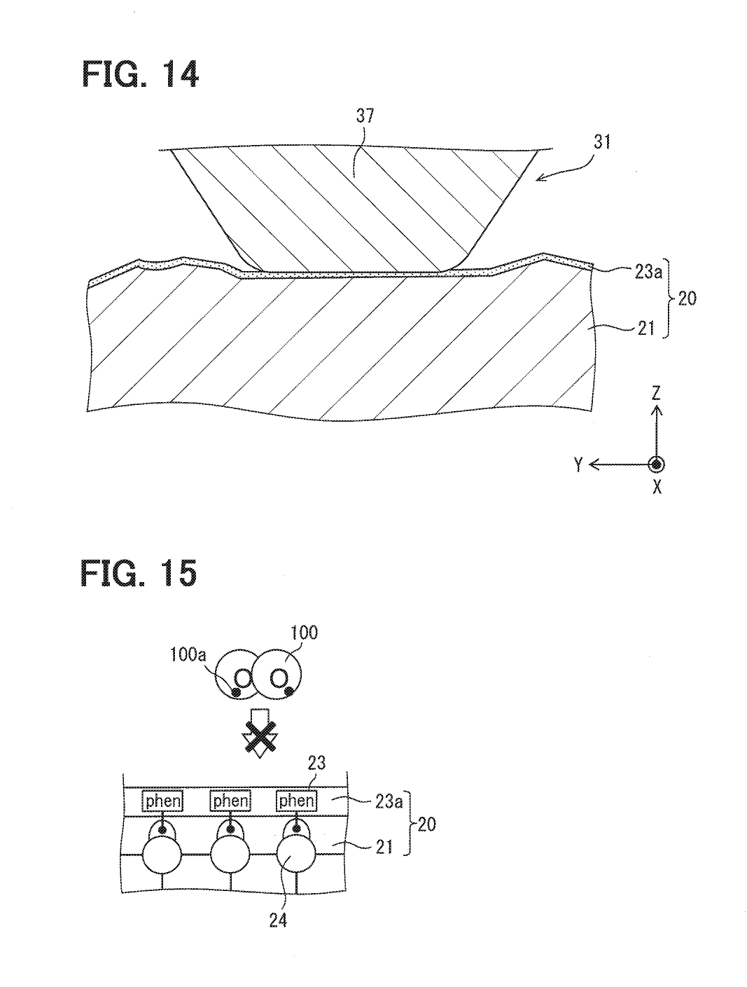

Referring to FIG. 14, in the present embodiment, the land 20 constituting the contact point part has an immersion film 23a containing π-accepting molecules 23 as a constituent material instead of the plated film 22 described above, as the thin film formed on the surface of the underlayer metal part 21 constituting the substrate.

The immersion film 23a is formed by immersing a contact point part of an electrical component into an immersion liquid (solution) containing π-accepting molecules 23 as a major component. The thickness of the immersion film 23a is extremely small to be 100 Å (0.01 μm) or less, so that electrical connection is established between the land 20 and the contact point part 37 by contact. When the thickness of the immersion film 23a is set to be 100 Å or less, the land 20 and the contact point part 37 can be electrically conducted with each other suitably by the tunnel effect.

FIG. 15 corresponds to FIG. 7 of the first embodiment. Referring to FIG. 15, in the present embodiment, the land 20 constituting the contact point part has the immersion film 23a together with the underlayer metal part 21. For this reason, the surface of the underlayer metal part 21 is the metal surface of the land 20. Also, the immersion film 23a is formed of π-accepting molecules 23.

Therefore, in the present embodiment as well, the π-accepting molecules 23 form a back-donation π-bond to the metal atoms 24 having a dangling bond in the same manner as in the first embodiment. This can reduce or eliminate the number of dangling bonds on the metal surface at the land 20, which is the contact point part, as compared with conventional cases. Therefore, oxidation of the metal surface can be suppressed at the land 20. Also, increase in the contact resistance can be suppressed for a longer period of time than in the conventional cases. Further, because gold is not used, oxidation of the metal surface can be suppressed at a low cost.

### Third Embodiment

For the present embodiment, reference can be made to the embodiments described before. For this reason, description of the parts common to those of the electronic device 10 shown in the embodiments described before will be omitted.

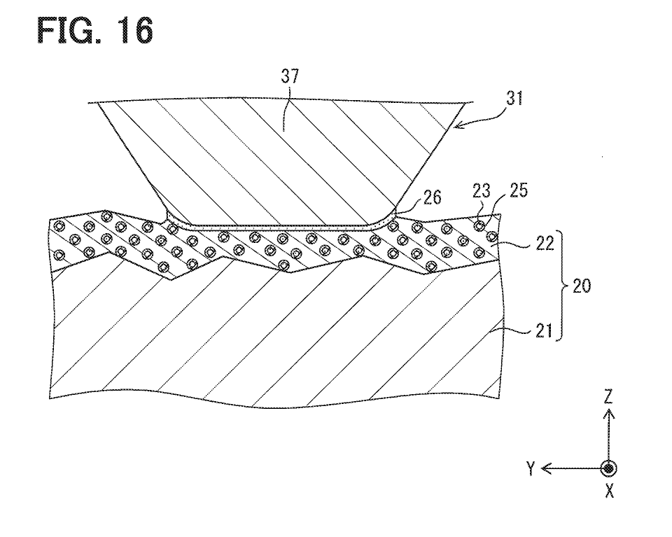

Referring to FIG. 16, the land 20 of the present embodiment has an underlayer metal part 21 and a plated film 22 in the same manner as in the first embodiment. The π-accepting molecules 23 are incorporated (enclosed) in a capsule 25. In other words, the π-accepting molecules 23 are enclosed as a core body of the capsule 25. Further, the capsules 25 are dispersed in the plated film 22.

The capsule 25 is what is known as a nanocapsule or a microcapsule. The capsule is formed by using, for example, a resin material. The capsule 25 has a size smaller than the thickness of the plated film 22 in order to be dispersed in the plated film 22. The capsule 25 has a size (diameter) of, for example, several ten μm or less.

For example, in establishing electrical connection by bringing the contact point part 37 of the terminal 31 and the land 20 into contact with each other, the capsules 25 are ruptured by friction caused by the contact of the contact point part 37, whereby the π-accepting molecules 23 are released. Further, a thin film 26 is formed at an electrical contact point by the released π-accepting molecules 23. The thin film 26 intervenes between the surface of the land 20 and the surface of the contact point part 37 constituting the electrical contact point. It is possible to say that the thin film 26 is formed on at least one of the surface of the land 20 and the surface of the contact point part 37 constituting the electrical contact point. The thickness of the thin film 26 is extremely small. For example, similarly to the immersion film 23a described above, the thin film 26 has a thickness of 100 Å (0.01 μm) or less. For this reason, electrical connection is established between the land 20 and the contact point part 37 even via the thin film 26. Since the thickness is 100 Å or less, the land 20 and the contact point part 37 can be electrically conducted with each other suitably by the tunnel effect.

In the present embodiment as well, the π-accepting molecules 23 constituting the thin film 26 form a back-donation π-bond to the metal atoms 24 having a dangling bond in the same manner as in the embodiments described above. This can reduce or eliminate the number of dangling bonds on the metal surface at the land 20, which is the contact point part, as compared with conventional cases. Therefore, oxidation of the metal surface can be suppressed at the land 20. Also, increase in the contact resistance can be suppressed for a longer period of time than in the conventional cases. Here, the π-accepting molecules 23 constituting the thin film 26 may form a back-donation π-bond to the metal atoms constituting the terminal 31, whereby oxidation of the surface of the contact point part at the terminal 31 can be suppressed as well.

The above-described structures of the embodiments are merely exemplifications, so that the scope of the present disclosure is not limited to the ranges described in these embodiments. The scope of the present disclosure is meant to include all changes and modifications comprised within the scope or being equivalent thereto.

The contact point part is not limited to the land 20 described above. At least the contact point part 37 of the card edge connector 12 may have the thin film containing the π-accepting molecules 23. Also, it is possible to adopt a configuration in which both of the land 20 and the contact point part 37 have the thin film containing the π-accepting molecules 23. In other words, it is sufficient that the contact point part of at least one of the two components (electrical components) constituting the electrical contact point has the thin film containing the π-accepting molecules 23.

The electrical component is not limited to the examples described above. An electrical relay member itself, such as a terminal or a leading wire, may constitute the electrical component. Also, an electronic component provided with a relay member may constitute the electrical component. For example, a contact point part of a press-fit terminal that establishes electrical connection between two boards may have the thin film containing the π-accepting molecules 23. Also, a contact point part of a terminal of an electronic component may have the thin film containing the π-accepting molecules 23. When the electrical component includes a relay member, the film containing the π-accepting molecules 23 is provided at at least the contact point part of the relay member.

Also, the land 20 of the board 11 is not limited to those formed on the surface of the board 11. A board 11 having a through-hole land may constitute the electrical component. In this case, through-hole plating constitutes a substrate, and the film containing the π-accepting molecules 23 is formed on the through-hole plating.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. An electrical component comprising:
a contact point part that establishes an electrical connection by contact,
wherein the contact point part includes:
a substrate having a metal as a constituent material; and
a thin film arranged at a surface of the substrate, and
wherein the thin film includes a π-accepting molecule having a π-acceptability, in which the π-accepting molecule has a size of ligand field splitting in a spectrochemical series larger than or equal to a size of ligand field splitting of 2,2′-bipyridyl.

2. The electrical component according to claim 1,
wherein the π-accepting molecule includes at least one of 1,10-phenanthroline and a 1,10-phenanthroline analog.

3. The electrical component according to claim 2,
wherein the π-accepting molecule is 1,10-phenanthroline in which an electron-attracting group is introduced to at least one of 2- to 9-positions of the 1,10-phenanthroline.

4. The electrical component according to claim 1,
wherein the π-accepting molecule includes at least one of 2,2′-bipyridyl and a 2,2′-bipyridyl analog.

5. The electrical component according to claim 4,
wherein the π-accepting molecule is 2,2′-bipyridyl in which an electron-attracting group is introduced to at least one of 3- to 6- and 3′- to 6′-positions of the 2,2′-bipyridyl.

6. The electrical component according to claim 1, wherein:
the thin film is a plated film; and
the π-accepting molecule is dispersed in the plated film.

7. The electrical component according to claim 6,
wherein the plated film includes one of Ni, Cu, Ag, and Co as a major component.

8. The electrical component according to claim 1,
wherein the thin film is an immersion film containing the π-accepting molecule as a constituent material.

9. The electrical component according to claim 1, wherein:
the π-accepting molecule is included in a capsule; and
the capsule is dispersed in the thin film.

10. An electronic device comprising:
a first component that has a first contact point part; and
a second component that has a second contact point part electrically connected to the first contact point part by being in contact with the first contact point part,
wherein at least one of the first component and the second component includes the electrical component according to claim 1.
